(19) United States
(12) Patent Application Publication
(10) Pub. No.: US 2024/0098931 A1
(43) Pub. Date: Mar. 21, 2024

(54) ANNULAR-SHAPED HEAT PIPE

(71) Applicant: Dell Products L.P., Round Rock, TX (US)

(72) Inventors: Dominick LOVICOTT, Jarrell, TX (US); Evangelos KOUTSAVDIS, Leander, TX (US)

(73) Assignee: Dell Products L.P., Round Rock, TX (US)

(21) Appl. No.: 17/946,863

(22) Filed: Sep. 16, 2022

(51) Int. Cl. H05K 7/20

(52) U.S. Cl. CPC H05K 7/20154; H05K 7/20172; H05K 7/20436

(57) ABSTRACT

An information handling system may include an air mover configured to drive an airflow, an information handling resource, and an annular-shaped heat pipe thermally coupled to the information handling resource and located downstream of the air mover and such that the airflow flows proximate to the annular-shaped heat pipe when the air mover drives the airflow.

### TECHNICAL FIELD

The present disclosure relates in general to information handling systems, and more particularly to an annular-shaped heat pipe for use in an information handling system.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

As processors, graphics cards, random access memory (RAM) and other components in information handling systems have increased in clock speed and power consumption, the amount of heat produced by such components as a side-effect of normal operation has also increased. Often, the temperatures of these components need to be kept within a reasonable range to prevent overheating, instability, malfunction and damage leading to a shortened component lifespan. Accordingly, air movers (e.g., cooling fans and blowers) have often been used in information handling systems to cool information handling systems and their components.

Further, heat-rejecting media such as heat pipes, heat spreaders, and heat sinks are often thermally coupled to heat-generating devices of information handling systems and placed in the airflow path of an air mover, to also aid in cooling of an information handling system and its components. However, in some situations, a high thermal performance may be required from a heat sink, but space restrictions and/or other restrictions may not allow for adequate heat sink fin area to meet the performance requirements.

### SUMMARY

In accordance with the teachings of the present disclosure, the disadvantages and problems associated with cooling in an information handling system may be substantially reduced or eliminated.

In accordance with embodiments of the present disclosure, an information handling system may include an air mover configured to drive an airflow, an information handling resource, and an annular-shaped heat pipe thermally coupled to the information handling resource and located downstream of the air mover and such that the airflow flows proximate to the annular-shaped heat pipe when the air mover drives the airflow.

In accordance with these and other embodiments of the present disclosure, a method may include thermally coupling an annular-shaped heat pipe to an information handling resource and locating the annular-shaped heat pipe downstream of an air mover such that an airflow driven from the air mover flows proximate to the annular-shaped heat pipe when the air mover drives the airflow.

In accordance with these and other embodiments of the present disclosure, heat-rejecting media may include an annular-shaped heat pipe configured to be thermally coupled to an information handling resource and located downstream of an air mover and such that an airflow generated by the air mover flows proximate to the annular-shaped heat pipe when the air mover drives the airflow.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of selected components of an example information handling system, in accordance with embodiments of the present disclosure; and

FIG. 2 illustrates a frontal elevation view of selected components of an example information handling system, in accordance with embodiments of the present disclosure.

### DETAILED DESCRIPTION

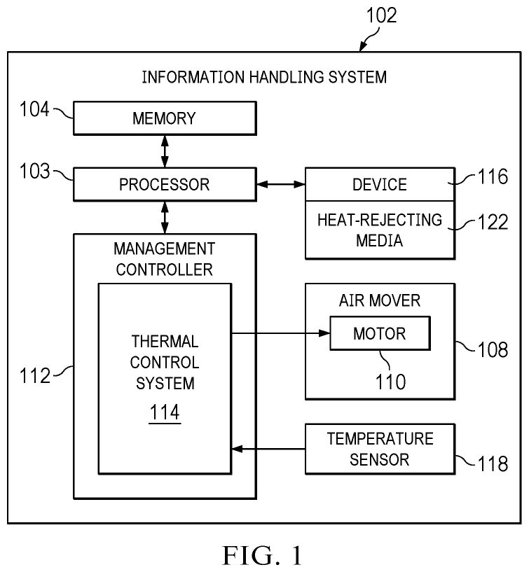

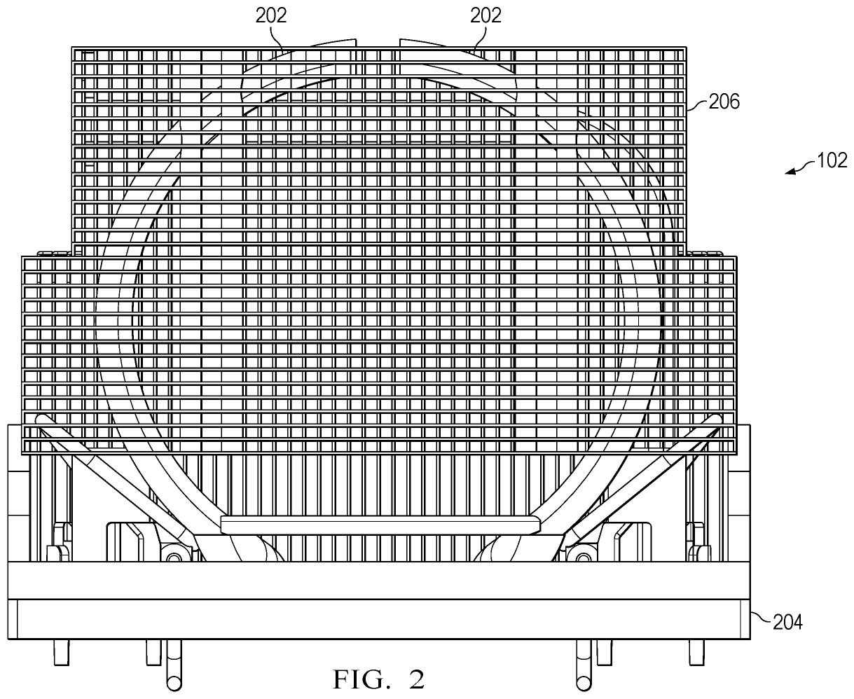

Preferred embodiments and their advantages are best understood by reference to FIGS. 1 and 2, wherein like numbers are used to indicate like and corresponding parts.

For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a PDA, a consumer electronic device, a network storage device, or any other suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include any instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory; as well as communications media such as wires, optical fibers, microwaves, radio waves, and other electromagnetic and/or optical carriers; and/or any combination of the foregoing.

For the purposes of this disclosure, information handling resources may broadly refer to any component system, device or apparatus of an information handling system, including without limitation processors, buses, memories, I/O devices and/or interfaces, storage resources, network interfaces, motherboards, integrated circuit packages, electro-mechanical devices (e.g., air movers), displays, and power supplies.

FIG. 1 illustrates a block diagram of selected components of an example information handling system 102, in accordance with embodiments of the present disclosure. In some embodiments, information handling system 102 may comprise a server chassis configured to house a plurality of servers or “blades.” In other embodiments, information handling system 102 may comprise a personal computer (e.g., a desktop computer, laptop computer, mobile computer, and/or notebook computer). In yet other embodiments, information handling system 102 may comprise a storage enclosure configured to house a plurality of physical disk drives and/or other computer-readable media for storing data. As shown in FIG. 1, information handling system 102 may comprise a processor 103, a memory 104 communicatively coupled to processor 103, an air mover 108, a management controller 112, a device 116 communicatively coupled to processor 103, a temperature sensor 118, and heat-rejecting media 122 thermally coupled to device 116.

Processor 103 may comprise any system, device, or apparatus operable to interpret and/or execute program instructions and/or process data, and may include, without limitation a microprocessor, microcontroller, digital signal processor (DSP), application specific integrated circuit (ASIC), or any other digital or analog circuitry configured to interpret and/or execute program instructions and/or process data. In some embodiments, processor 103 may interpret and/or execute program instructions and/or process data stored in memory 104 and/or another component of information handling system 102.

Memory 104 may be communicatively coupled to processor 103 and may comprise any system, device, or apparatus operable to retain program instructions or data for a period of time. Memory 104 may comprise random access memory (RAM), electrically erasable programmable read-only memory (EEPROM), a PCMCIA card, flash memory, magnetic storage, opto-magnetic storage, or any suitable selection and/or array of volatile or non-volatile memory that retains data after power to information handling system 102 is turned off.

Air mover 108 may include any mechanical or electro-mechanical system, apparatus, or device operable to move air and/or other gases in order to cool information handling resources of information handling system 102. In some embodiments, air mover 108 may comprise a fan (e.g., a rotating arrangement of vanes or blades which act on the air). In other embodiments, air mover 108 may comprise a blower (e.g., a centrifugal fan that employs rotating impellers to accelerate air received at its intake and change the direction of the airflow). In these and other embodiments, rotating and other moving components of air mover 108 may be driven by a motor 110. The rotational speed of motor 110 may be controlled by an air mover control signal (e.g., a pulse-width modulation signal) communicated from thermal control system 114 of management controller 112. In operation, air mover 108 may cool information handling resources of information handling system 102 by drawing cool air into an enclosure housing the information handling resources from outside the chassis, expel warm air from inside the enclosure to the outside of such enclosure, and/or move air across one or more heat sinks (not explicitly shown) internal to the enclosure to cool one or more information handling resources.

Management controller 112 may comprise any system, device, or apparatus configured to facilitate management and/or control of information handling system 102 and/or one or more of its component information handling resources. Management controller 112 may be configured to issue commands and/or other signals to manage and/or control information handling system 102 and/or its information handling resources. Management controller 112 may comprise a microprocessor, microcontroller, DSP, ASIC, field programmable gate array (“FPGA”), EEPROM, or any combination thereof. Management controller 112 also may be configured to provide out-of-band management facilities for management of information handling system 102. Such management may be made by management controller 112 even if information handling system 102 is powered off or powered to a standby state. In certain embodiments, management controller 112 may include or may be an integral part of a baseboard management controller (BMC), a remote access controller (e.g., a Dell Remote Access Controller or Integrated Dell Remote Access Controller), or an enclosure controller. In other embodiments, management controller 112 may include or may be an integral part of a chassis management controller (CMC).

As shown in FIG. 1, management controller 112 may include a thermal control system 114. Thermal control system 114 may include any system, device, or apparatus configured to receive one or more signals indicative of one or more temperatures within information handling system 102 (e.g., one or more signals from one or more temperature sensors 118) and based on such one or more signals, calculate an air mover driving signal (e.g., a pulse-width modulation signal) to maintain an appropriate level of cooling, increase cooling, or decrease cooling, as appropriate, and communicate such air mover driving signal to air mover 108. Thermal control for air mover 108 by thermal control system 114 may be performed in any suitable manner, for example, as described in U.S. Pat. No. 10,146,190 entitled “Systems and Methods for Providing Controller Response Stability in a Closed-Loop System.”

In addition, thermal control system 114 may also be configured to maintain acoustic limits and/or maintain acoustic preferences for sound generated by air mover 108, for example, as described in U.S. patent application Ser. No. 16/852,118, filed Apr. 17, 2020, and entitled “Systems and Methods for Acoustic Limits of Thermal Control System in an Information Handling System,” which is incorporated by reference herein in its entirety.

In some embodiments, thermal control system 114 may include a program of instructions (e.g., software, firmware) configured to, when executed by a processor or controller integral to management controller 112, carry out the functionality of thermal control system 114.

Device 116 may comprise any component information handling system of information handling system 102, including without limitation processors, buses, memories, I/O devices and/or interfaces, storage resources, network interfaces, motherboards, integrated circuit packages; electro-mechanical devices, displays, and power supplies.

Temperature sensor 118 may comprise any system, device, or apparatus (e.g., a thermometer, thermistor, etc.) configured to communicate a signal to thermal control system 114 indicative of a temperature within information handling system 102.

Heat-rejecting media 122 may include any system, device, or apparatus configured to transfer heat from an information handling resource (e.g., device 116, as shown in FIG. 1), thus reducing a temperature of the information handling resource. For example, heat-rejecting media 122 may include one or more solids thermally coupled to the information handling resource (e.g., heat pipe, heat spreader, heatsink, finstack, etc.) such that heat generated by the information handling resource is transferred from the information handling resource. Further, heat-rejecting media 122 may be arranged to be located within the airflow path of airflow generated by air mover 108, such that heat transferred to heat-rejecting media 122 from device 116 may further be transferred to such airflow. In some embodiments, heat-rejecting media 122 may include an annular-shaped heat pipe, such as that shown in FIG. 2 and described below. Although, for purposes of clarity and exposition, heat-rejecting media 122 is shown as being thermally coupled to device 116, it is understood that heat-rejecting media 122 may also be thermally coupled to other information handling resources (e.g., processor 103 and/or memory 104) of information handling system 102 in addition to or in lieu of being thermally coupled to device 116.

In addition to processor 103, memory 104, air mover 108, management controller 112, device 116, temperature sensor 118, and heat-rejecting media 122, information handling system 102 may include one or more other information handling resources. In addition, for the sake of clarity and exposition of the present disclosure, FIG. 1 depicts only one air mover 108 and temperature sensor 118. In embodiments of the present disclosure, information handling system 102 may include any number of air movers 108 and temperature sensors 118.

FIG. 2 illustrates a front elevation view of selected components of information handling system 102, in accordance with embodiments of the present disclosure. As shown in FIG. 2, heat-rejecting media 122 of information handling system 102 may comprise one or more annular-shaped heat pipes 202 thermally coupled to device 116 (not explicitly shown in FIG. 2) which itself may be communicatively and mechanically coupled to motherboard 204. Annular-shaped heat pipes 202 may be thermally and mechanically coupled to device 116 and/or motherboard 204 in any suitable manner, including without limitation adhesives, fasteners, and/or other mechanical loading devices. As its name indicates, an annular-shaped heat pipe 202 may be annular shaped, that is, shaped in a manner such that the annular-shaped heat pipe 202 forms at least a portion of an ellipse. As also shown, heat-rejecting media 122 may also include a heat spreader 206 thermally coupled to the one or more annular-shaped heat pipes 202 to further aid in dissipation of heat.

Such annular shape of an annular-shaped heat pipe 202 may be advantageous, as computational fluid dynamics simulations performed by the applicant have shown that a high-speed annular region of air flow may exist downstream of air mover 108 (e.g., when air mover 108 is implemented using a fan), especially in close proximity to the airflow exhaust from air mover 108. In other words, a profile of the airflow driven from an air mover 108 may have a generally annular region at which airflow is at a significantly greater speed than airflow generated by the air mover but outside the generally annular region.

Thus, in operation, annular-shaped heat pipe 202 may be located relative to air mover 108 such that air flow downstream of air mover 108 is proximate to annular-shaped heat pipe 202. In some embodiments, annular-shaped heat pipe 202 may be located relative to air mover 108 such that annular-shaped heat pipe 202 is within a high-speed annular airflow region generated by air mover 108, at least at certain speeds of air mover 108.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. An information handling system comprising:
an air mover configured to drive an airflow;
an information handling resource; and
an annular-shaped heat pipe thermally coupled to the information handling resource and located downstream of the air mover and such that the airflow flows proximate to the annular-shaped heat pipe when the air mover drives the airflow.

2. The information handling system of claim 1, further comprising a heat spreader thermally coupled to the annular-shaped heat pipe.

3. The information handling system of claim 1, wherein the annular-shaped heat pipe is located relative to the air mover such that the annular-shaped heat pipe is within a generally annular region of airflow driven by the air mover for at least certain speeds of the air mover, wherein the generally annular region airflow is at a significantly greater speed than airflow generated by the air mover but outside the generally annular region.

4. A method comprising:
thermally coupling an annular-shaped heat pipe to an information handling resource; and
locating the annular-shaped heat pipe downstream of an air mover such that an airflow driven from the air mover flows proximate to the annular-shaped heat pipe when the air mover drives the airflow.

5. The method of claim 4, further comprising thermally coupling a heat spreader to the annular-shaped heat pipe.

6. The method of claim 4, wherein locating the annular-shaped heat pipe comprises locating the annular-shaped heat pipe relative to the air mover such that the annular-shaped heat pipe is within a generally annular region of airflow driven by the air mover for at least certain speeds of the air mover, wherein the generally annular region airflow is at a significantly greater speed than airflow generated by the air mover but outside the generally annular region.

7. Heat-rejecting media comprising an annular-shaped heat pipe configured to be:
thermally coupled to an information handling resource; and
located downstream of an air mover and such that an airflow generated by the air mover flows proximate to the annular-shaped heat pipe when the air mover drives the airflow.

8. The heat-rejecting media of claim 7, further comprising a heat spreader thermally coupled to the annular-shaped heat pipe.

9. The heat-rejecting media of claim 7, wherein the annular-shaped heat pipe is configured to be located relative to the air mover such that the annular-shaped heat pipe is within a generally annular region of airflow driven by the air mover for at least certain speeds of the air mover, wherein the generally annular region airflow is at a significantly greater speed than airflow generated by the air mover but outside the generally annular region.
